(19) United States
(12) Patent Application Publication
(10) Pub. No.: US 2005/0136673 A1
(43) Pub. Date: Jun. 23, 2005

(54) CMP slurry

(76) Inventors: Wen-Qing (Peter) Xu, Northborough, MA (US); Sharath Hegde, Potsdam, NY (US)

Correspondence Address: CALFEE HALTER & GRISWOLD, LLP, 800 SUPERIOR AVENUE, SUITE 1400, CLEVELAND, OH, 44114, US

(21) Appl. No.: 11/057,559

(22) Filed: Feb. 14, 2005

Related U.S. Application Data
(62) Division of application No. 10/635,949, filed on Aug. 7, 2003.

(51) Int. Cl. H01L 21/302; H01L 21/461

(52) U.S. Cl. 438/693

(57) ABSTRACT

RNA, DNA and the building blocks forming these compounds provide significant enhancement in the selectivity of a CMP slurry for removing silicon dioxide in preference to silicon nitride during chemical-mechanical polishing in the manufacture of semiconductor wafers and chips by STI.

### FIELD

The present invention relates to chemical/mechanical polishing (“CMP”) slurries and to CMP process using such slurries.

### BACKGROUND

U.S. Pat. No. 6,491,843 B1 describes certain CMP slurries having high selectivities for removing silicon dioxide in preference to silicon nitride. These slurries are composed of water, abrasive particles and a selectivity enhancer comprising an organic compound having both a carboxylic acid functional group and a second functional group selected from amines and halides. Amino acids and especially proline, glycine, alanine, arginine and lysine are preferred. See, also, U.S. Pat. No. 6,544,892 B2 and U.S. Pat. No. 6,468,910 B1.

### SUMMARY OF THE INVENTION

It has now been found that CMP slurries in which the selectivity enhancer is a nucleic acid related compound, e.g., RNA, DNA, a nitrogen-containing precursor of RNA or DNA, a nitrogen-containing decomposition product of RNA or DNA, or mixtures of any of these compounds, also exhibit high selectivities for removing silicon dioxide in preference to silicon nitride.

Thus, the present invention provides a novel CMP slurry for use in chemical-mechanical polishing in the manufacture of a wafer or chip, the slurry comprising Water, abrasive particles and a selectivity enhancer for causing the slurry to selectively remove silicon dioxide in preference to silicon nitride, the selectivity enhancer comprising a nucleic acid related compound, more particularly RNA or DNA, a nitrogen-containing precursor of RNA or DNA, a nitrogen-containing decomposition product of RNA or DNA, or mixture of any of these compounds.

### DETAILED DESCRIPTION

Chemical Mechanical Polishing

Chemical mechanical polishing is well known technology in which the workpiece is rubbed with a polishing pad while a CMP slurry is applied to the interface between the pad and the surface being polished. The CMP slurry functions to chemically react with the surface while the abrasive particles in the slurry mechanically abrade the surface.

Chemical mechanical polishing is used extensively in the manufacture of semiconductor chips and wafers by the shallow trench isolation (“STI”) technique. In STI, a pattern of shallow trenches is made in the surface of a silicon or gallium arsenide wafer carrying a silicon nitride barrier layer, the trenches normally being space apart by distances as small as a few nanometers and as large as several thousand microns, more typically about 0.065-5000 microns or even 0.09-3000 microns. A dielectric such as silicon dioxide is then deposited by chemical vapor deposition, for example, to completely fill the trenches in such a way that the dielectric also forms a silicon dioxide overburden covering the silicon nitride barrier layer. The process may over fill the trenches. CMP is then used to remove the dielectric overburden covering the silicon nitride barrier layer and remove any overfills on the trenches, and ideally stop at the silicon nitride barrier layer without dishing into the dielectric trenches, which produces a completely planar surface. In subsequent steps, the silicon nitride barrier layer is removed, polysilicon gate structures are formed in the wafer surfaces between the dielectric-filled trenches. For a complete description of STI and CMP, see: U.S. Pat. Nos. 6,491,843 B1; 6,365,520; 5,738,800; 6,548,373 B1; 5,759,917; 5,772;780; 6,043;155; 6,343,976 B1; 6,544,892 B2; 6,468,910 B1; 6,303,506; U.S. 2003/0092271 A1; EP 0 846 740 A1 and EP 0 853 335 A2, the disclosures of which are incorporated herein by reference.

CMP Slurries

The inventive CMP slurries are composed of water or other slurry liquid, abrasive particles and at least one selectivity enhancing nucleic acid related compound. Additional optional organic and inorganic compounds may also be included.

Like most conventional CMP slurries, the inventive CMP slurries use water as the slurry liquid. However, other liquids which will accomplish the same purpose can also be used. Examples are methanol, ethanol and the other alcohols, glycols, ketones and aldehydes.

Any type of abrasive particles can be used in the inventive CMP slurries. Examples include silica, alumina, ceria, copper oxide, iron oxide, nickel oxide, manganese oxide, silicon carbide, silicon nitride, tin oxide, titania, tungsten oxide, yttria, zirconia, complex oxides such as zinc ferrite, magnesium ferrite, aluminum silicate and barium carbonate, various metal carbides such as titanium carbide, metal hydroxides such as aluminum hydroxide, magnesium hydroxide, manganese hydroxide and cerium hydroxide, as well as organic abrasives such as polystyrene, urea-formaldehyde and latex particles. Mixtures of these abrasives can also be used. Silica, alumina, titania, ceria and mixtures thereof are most often used.

The particle size of the abrasive particles of the inventive CMP slurries can vary widely, and essentially any conventional particle size can be used. In this connection, care should be taken to avoid particles which are too large, which may lead to unacceptable scratching, as well as particles which are too small, which may lead to unacceptably low polishing rates. In general, this means that the mean particle size should be between about 0.001-10 microns, more typically between 0.005-5.0 microns, or even 0.01-2.0 microns, with particles larger than about 10 microns preferably being avoided essentially completely for polishing wafers for semiconductor manufacture. In addition, a bimodal particle size distribution, i.e., a mixture of small and large particles as described in U.S. Pat. No. 6,365,520 B1, can be used.

The concentration of abrasive particles in the inventive CMP slurries can also vary widely, and essentially any conventional amount can also be used. Typically, this means the slurry will contain about 0.01-50 wt. % particles, with 0.05-30 wt. % and even 0.1-10 wt. % being more typical.

In addition to the abrasive particles, the inventive CMP slurries can contain a wide variety of optional ingredients. For example, the inventive CMP slurries can contain anionic and cationic surfactants such as shown, for example, in U.S. Pat. Nos. 5,738,800 and 6,303,506. In addition, the inventive CMP slurries can contain organic compounds having a carboxylic acid group and an electrophilic functional group such as an amine or halide such as shown, for example, in U.S. Pat. Nos. 6,491,843 B1; 6,544,892 B1 and U.S. Pat. No. 6,468,910 B1. Similarly, the inventive CMP slurries can contain simple carboxylic acids such as shown in U.S. Pat. No. 5,759,917, alone or in combination with a water-soluble salt and soluble cerium compounds as further shown in that patent, as well as organic particles containing carboxyl and other anionic groups such as shown in U.S. Pat. No. 6,559,056 B2. The inventive CMP slurries can also contain acids, bases and other compounds for adjusting pH, such as the tetramethyl ammonium hydroxide shown in EP 0 853 335 and the polyelectrolytes shown in EP 0 846 740 A1 such as the polyethylenimine and other organic and inorganic compounds previously used in these slurries such as the H₂O₂ of U.S. Pat. No. 6,043,155.

Nucleic Acid Compounds

In accordance with the present invention, the inventive CMP slurries contain at least one nucleic acid related compound as a selectivity enhancer. By “nucleic acid related compound” is meant ribonucleic acid compounds (“RNA”) and deoxyribonucleic acid compounds (“DNA”), as well as the nucleotides, nucleosides and heterocyclic amine bases which are the nitrogen-containing precursors of or decomposition products of these RNA and DNA compounds, and mixtures of these compounds. Nucleotides which are not derived from or decomposition products of RNA and DNA are also “nucleic acid related compounds” for the purposes of this invention. Also included are synthetic analogs of such compounds.

RNA and DNA molecules are polynucleotides, i.e., polymers which are formed when the same or different nucleotides polymerize. A nucleotide, in turn, is formed from a nucleoside, which is a unit composed of one sugar combined with one heterocyclic amine base, and a phosphate unit attached to the 5′-position of the sugar.

In the synthesis of RNA and DNA molecules in nature, a single phosphate group attaches to the 5′-position of the sugar and thereafter the heterocyclic amine base combines with or is built up upon the sugar to form a monophosphate nucleotide. Then, an additional phosphate group attaches to the existing phosphate group to form a diphosphate nucleotide. Thereafter, a third phosphate group attaches to the second phosphate group to form a triphosphate nucleotide. Only the triphosphate nucleotides polymerize. In this reaction, the second and third phosphate groups sever from the first phosphate group, which in turn links to the C5′ position of the adjacent sugar.

Nucleosides can be obtained from the decomposition (hydrolysis) of RNA and DNA. Nucleotides are found in nature and can be obtained by isolation from organic matter. All RNA and DNA molecules are formed from two specific sugars and five specific heterocyclic amine bases. The sugars are ribose and deoxyribose. The heterocyclic bases are adenine and guanine, which are substituted purines, and cytosine, uracil and thymine, which are substituted pyrimidines. Uracil is found only in RNA, while thymine is found only in DNA. The other three are found in both RNA and DNA. Synthetic analogs of these compounds are also known and are useful in this invention. Thus,

Thus, there are a total of eight different nucleosides which can be present in and which can be recovered from RNA and DNA, namely adenosine, 2′-deoxyadenosine, guanosine, 2′-deoxyguanosine, cytidine, 2′-deoxycytidine, uridine and 2′-deoxythymidine.

Similarly, there are a total of 24 different nucleotides which form during the synthesis of RNA and DNA and can be recovered from organic matter. The monophosphate nucleotides are adenosine 5′-phosphate, 2′-deoxyadenosine 5′-phosphate, guanosine 5′-phosphate, 2′-deoxyguanosine 5′-phosphate, cytidine 5′-phosphate, 2′-deoxycytidine 5′-phosphate, uridine 5′-phosphate and 2′-deoxythymidine 5′-phosphate. The diphosphate nucleotides are adenosine 5′-diphosphate, 2′-deoxyadenosine 5′-diphosphate, guanosine 5′-diphosphate, 2′-deoxyguanosine 5′-diphosphate, cytidine 5′-diphosphate, 2′-deoxycytidine 5′-diphosphate, uridine 5′-diphosphate and 2′-deoxythymidine 5′-diphosphate. The triphosphate nucleotides are adenosine 5′-triphosphate, 2′-deoxyadenosine 5′-triphosphate, guanosine 5′-triphosphate, 2′-deoxyguanosine 5′-triphosphate, cytidine 5′-triphosphate, 2′-deoxycytidine 5′-triphosphate, uridine 5′-triphosphate and 2′-deoxythymidine 5′-triphosphate.

Synthetic analogs of such compounds are also useful in the present invention. For example, 5-fluorocytidine and 5-fluorouridine are commercially-available and useful in the present invention. In addition, the chloro, iodo, thio and mercapto analogs of these compounds are also useful, as are the corresponding 6-substituted compounds as well as the corresponding substituted adenine, guanine and thymine compounds. Nucleotides formed from these compounds are also useful.

For a further description of the chemistry of RNA and DNA, see pages 1107-1149 of Organic Chemistry, 3^{rd} Edition, by John MaMurrry, Brooks/Cole Publishing Company, 1992. See, also, Lehninger, Biochemistry, Second Edition, Worth Publishers, Inc., pp. 729-747, © 1975. See, also, King et al., Chemistry of Nucleic Acids, Version May 11, 2002, available on the web at http://www.med.unibs.it/˜marchesi/nucleic.html. Note, especially, the portion of this article on pages 7 and 8 relating to synthetic nucleotides, which reads as follows:

### Synthetic Nucleotide Analogs

“Many nucleotide analogues are chemically synthesized and used for their therapeutic potential. The nucleotide analogues can be utilized to inhibit specific enzymatic activities. A large family of analogues are used as anti-tumor agents, for instance, because they interfere with the synthesis of DNA and thereby preferentially kill rapidly dividing cells such as tumor cells. Some of the nucleotide analogues commonly used in chemotherapy are 6-mercaptopurine, 5-fluorouracil, 5-iodo-2′-deoxyuridine and 6-thioguanine. Each of these compounds disrupts the normal replication process by interfering with the formation of correct Watson-Crick base-pairing.

Nucleotide analogs also have been targeted for use as antiviral agents. Several analogs are used to interfere with the replication of HIV, such as AZT (azidothymidine) and ddI (dideoxyinosine). Several purine analogs are used to treat gout. The most common is allopurinol, which resembles hypoxanthine. Allopurinol inhibits the activity of xanthine oxidase, an enzyme involved in de novo purine biosynthesis. Additionally, several nucleotide analogues are used after organ transplantation in order to suppress the immune system and reduce the likelihood of transplant rejection by the host.”

In accordance with the present invention, it has been found that these nucleic acid related compounds also cause CMP slurries to exhibit a significant improvement in selectivity for removing silicon dioxide in preference to silicon nitride during CMP polishing in the manufacture of semiconductor wafers and chips. Thus, the inventive CMP slurries contain at least one of the nucleic acid related compound mentioned above, i.e., at least one RNA or DNA compound and/or at least one of the nitrogen-containing precursors forming these polymer compounds and/or the nitrogen-containing decomposition products derived from these compounds, i.e., the nucleotides, nucleosides and heterocyclic amine bases mentioned above. These compounds can be used individually or in admixtures.

The amount of nucleic acid compound that should be included in the inventive CMP slurries can vary widely, and essentially any amount can be used. In this connection, some RNA, DNA and the other nucleic acid related compounds mentioned above are water soluble, and some are water-soluble by adjusting the pH. So it is preferable not to use more than a saturation amount since additional amounts will precipitate out or agglomerate and provide essentially no incremental benefit. Similarly, enough nucleic acid related compound should be used to provide a noticeable enhancement in selectivity during CMP polishing, i.e., selectivity for removing silicon dioxide in preference to silicon nitride. Within these parameters, however, essentially any amounts can be used. Typically, this means that the amount of nucleic acid compound will be about 0.01-50 wt. %, more typically about 0.1-20 wt. % or even about 0.5 to 10 wt. %.

Mixed Surfactants

In a particular embodiment of the present invention, it has been found that CMP slurries of the present invention, when containing a mixture of anionic, cationic and non-ionic surfactants, exhibit an enhanced ability to eliminate pits and reduce surface roughness in the surfaces being polished.

In this connection, U.S. Pat. No. 6,303,506 B1 to Nojo et al., the disclosure of which is incorporated herein by reference, describes aqueous slurry-less compositions for CMP processing which contains a cationic surfactant. The use of cationic surfactant is said to reduce scratches and polishing defects during slurry-less CMP processing of silicon wafer surfaces. Mixtures of cationic, anion and nonionic surfactants can also be used. In accordance with this aspect of the present invention, it has been found that mixtures of cationic surfactants, nonionic surfactants, and anionic surfactants will also enhance surface smoothness and prevent the pits formation when used in the inventive CMP slurries.

In carrying out this aspect of the present invention, any type of cationic, anionic and nonionic surfactants can be used. In this regard, see WO 96/16154, the disclosure of which is incorporated herein by reference, which describes a wide variety of different cationic, anionic and nonionic surfactants, all of which can be used in accordance with this aspect of the present invention.

Preferred surfactants are those described in the above-noted U.S. Pat. No. 6,303,506 B1. Thus, preferred cationic surfactants are alkyltrimethylammonium halides and especially the C₉₋₁₃alkyltrimethylammonium halides, alkylbenzyldimethylammonium halides and especially the C₆₋₁₈alkylbenzyldimethylammonium halides, pyridiniumalkyl halides and especially the C₆₋₁₈pyridiniumalkyl halides and the alkylammonium esters, especially the C₆₋₁₈alkylammonium esters. Particularly preferred are hexadecyltrimethylammonium bromide, hexadecylbenzyldimethylammonium bromide, dodecylbenzyldimethylammonium bromide, cetylpyridinium chloride and dodecylammonium acetate.

Preferred anionic surfactants are polymers containing carboxylic acid or salt groups such as polymers and copolymers of acrylic acid and methacrylic acid and ammonium salts thereof as well as analogous salts such as the sodium, potassium, cesium, monoethanolamine, diethanolamine, and triethanolamine salts, soap, and so forth. Also useful are the C₁₂₋₁₈alkyl sulfates, the C₉₋₁₃alkyl benzenesulfonates, the C₈₋₂₂primary or secondary alkanesulfonates, C₈₋₂₄olefinsulfonates, sulfonated polycarboxylic acids, C₈₋₂₄alkylpolyglycolethersulfates, and so forth.

Preferred nonionic surfactants are water soluble polymers such as polyvinyl alcohol, polyacrylamide and polyvinylpyrrolidone, preferably having a molecular weight of less than 20,000. Other nonionic surfactants are the condensation products of ethylene oxide and/or propylene oxide with alkyl phenols, primary and/or secondary alcohols, and the polyhydroxy fatty acid amides.

The concentrations of these surfactants in the inventive CMP slurries can vary widely, and essentially any amount can be used. Typical concentrations run from 0.001-10 wt. %, 0.02-5 wt. %, or even 0.05 to 3 wt. % in total. Also, it is desirable that the concentration of the nonionic surfactant be greater than that of the cationic surfactant while the concentration of the anionic surfactant be greater than that of the nonionic surfactant. Preferably, the concentration of the nonionic surfactant is 5-15 times greater than that of the cationic surfactant while the concentration of the anionic surfactant is 5-15 greater than that of the nonionic surfactant.

### EXAMPLES

In order to more thoroughly describe the present invention, the following working examples are provided.

### Examples 1-4 and Comparative Examples A-D

In these examples, two types of blanket silicon wafers 6 inches (about 15 cm.) in diameter were used. One type was a silicon dioxide blanket wafer formed by thermal oxidation with a SiO₂ thickness of 10,000 Å on silicon. Another type was a silicon nitride blanket wafer with a silicon nitride layer of a thickness of 2500 Å over a SiO₂ layer of 100 Å thick. Both types of silicon dioxide and silicon nitride blanket wafers were subjected to CMP polishing for one minute using a Westech Model 372 polisher equipped with a Rodel's IC-1400 K-groove polishing pad. Both platen rotation speed and carrier rotation speed were at 75 rpm. The pad was conditioned for 1 minutes for every polishing run. A down pressure of 4 PSI was applied to the polishing head without any back pressure. Polishing slurry was supplied to the polisher at 200 milliliters per minute. After polishing was done, each wafer was cleaned with water and dried with ethanol (compressed air drying). The polished wafer was then characterized with different metrology tools including thickness measurements and surface roughness measurements. The selectivity of each polishing slurry, i.e., ratio of the removal rate of silicon dioxide (thermal oxide blanket wafers) to the removal rate of silicon nitride (silicon nitride blanket wafers) with that particular slurry, was also calculated.

Each slurry of the present invention was composed of water, an abrasive mixture comprising 0.5 wt. % 0.2 micron (200 nm) ceria particles and 1.0 wt. % 0.015 micron (15 nm) ceria particles, 0.33-2.0 wt. % of an anionic surfactant comprising polyacrylic acid (“PA”), 0.05 wt. % of a nonionic surfactant comprising polyacrylamide and 0.0033 wt. % of a cationic surfactant comprising cetyl pryidinium chloride. Each slurry also contained 2.0 wt. % of a nucleic acid related compound in accordance with the present invention, unless otherwise indicated. Each slurry of the comparative examples contained the same ingredients in the same amounts, except that the nucleic acid selectivity enhancing compounds of the present invention were replaced with 2.0 wt. % of other selectivity enhancing organic compounds or nothing at all.

Polishing was continued for 1 minute, after which the thickness of either silicon dioxide or silicon nitride was measured and the rate at which the SiO₂ and silicon nitride were removed were calculated. The results obtained are set forth in the following Table 1:

TABLE 1
Selectivities of Different CMP Slurries

| | PA | | | | SiO₂ | | |
|---|---|---|---|---|---|---|---|
| | conc | Selectivity | Peak to | RMS Surface | Removal | SiN Removal | SiO₂/SiN |
| Ex | wt. % | Enhancer | Valley, \acute{Å} | Roughness, \acute{Å} | Rate, \acute{Å}/min | Rate, \acute{Å}/min | Selectivity |
| 1 | 0.5 | ADP¹ | 32 | 3.5 | 2750 ± 290 | 160 ± 30 | 17 |
| 2 | 0.5 | uridine | 40 | 5.0 | 3520 ± 460 | 80 ± 10 | 44 |
| 3 | 0.5 | cytidine | 33 | 3.9 | 2350 ± 240 | 50 ± 10 | 47 |
| 4 | 0.5 | ADP² | 38 | 3.9 | 2700 ± 350 | 245 ± 120 | 11 |
| A | 0.5 | None | 38 | 3.6 | 2740 ± 380 | 913 ± 50 | 3.0 |
| B | 0.5 | proline | 30 | 3.6 | 3010 ± 280 | 60 ± 40 | 50 |
| C | 2.0 | proline | 65 | 6.4 | 3460 ± 260 | 824 ± 190 | 4.2 |
| D | 0.33 | proline | 39 | 4.2 | 2920 ± 250 | 70 ± 40 | 42 |

2.0 wt. % adenosine 5′-phosphate
0.5 wt. % adenosine 5′-phosphate

From Table 1, it can be seen that the CMP slurries of the present invention provided significantly enhanced selectivities for SiO₂ removal in preference to SiN removal as compared with a control composition containing no selectivity enhancer (Comparative Example A). In addition, the level of selectivity enhancement provided by the CMP slurries of the present invention, at least when the selectivity enhancing compound used was a nucleoside, specifically uridine or cytidine (Examples 2 and 3), was comparable to that provided by the prior art amino acid proline (Comparative Example B).

### Example 5

In this example, the inventive CMP slurry was used in the CMP processing of patterned wafers to demonstrate the planarization capability and selectivity of the inventive slurry. STI patterned wafers 8 inches in diameter were obtained from SKW Associates. The wafers are characterized by areas of differing line widths and relative line areas in order to allow characterization of the CMP capability of the CMP slurry. The wafers are further characterized as having 1400 Å of silicon nitride as a barrier layer, with a trench depth of 4000 Å and a top layer of 7000 Å. The objective of CMP was to remove the top layer silicon dioxide covering the silicon nitride barrier layer and the trenches without appreciable loss of silicon nitride or dishing of silicon oxide in the trench area.

The wafers were then polished by CMP processing using a Westech Model 372M (472) polisher equipped with a Rodel's IC-1400 with K-groove polishing pad. Both platen rotation speed and carrier rotation speed were at 75 rpm. The pad was conditioned for 1 minute for every polishing run. A down pressure of 6 PSI down pressure was applied to the polishing head with a 2 PSI back pressure. A CMP slurry of the present invention was supplied to the polisher at 200 milliliters per minute, the slurry having the following composition:
0.5 wt. % ceria (0.3 microns)
0.5 wt. % polyacrylic acid (anionic surfactant)
0.05 wt % polyacrylamide (nonionic surfactant)
0.0033 wt. % cetylpyridinium chloride (cationic surfactant)
2 wt. % cytidine (1%)+uridine (1%)

After polishing was done, each wafer was cleaned with water and dried with ethanol (compressed air drying). The polished wafer was then characterized with different metrology tools including thickness measurements, surface roughness measurements, step height measurements.

The following results were obtained:

The silicon dioxide overburden layer over the silicon nitride barrier layer was removed across the wafer with little loss of silicon nitride for feature densities of 30% to 100%. There was still 50% retention of silicon nitride at 20% feature density. It is expected that with optimization of the CMP process even better results can be obtained.

Dishing was evaluated on 100 micron feature widths and found to be less than 600 Å across the wafer. This is considered good for this application.

From this example, it can be seen that the inventive CMP slurry is capable of allowing selective removal of the silicon dioxide overburden while minimizing silicon nitride barrier layer loss in actual structured wafers.

Although only a few embodiments of the present invention have been described above, it should be appreciated that many modifications can be made without departing from the spirit and scope of the present invention. All such modifications are intended to be included within the scope of the present invention, which is to be limited only by the following claims:

1-13. (canceled)

14. A chemical-mechanical polishing process for selectively removing silicon dioxide from the surface of a workpiece containing surface areas of silicon dioxide and surface areas of silicon nitride in which the surface to be polished is contacted with a polishing pad and a CMP slurry is applied to the interface between the polishing pad the surface to be polished,
wherein the CMP slurry comprises a liquid, abrasive particles and a selectivity enhancer for enhancing the removal of silicon dioxide in preference to the removal of silicon nitride, the selectivity enhancer comprising a nucleic acid related compound.

15. The process of claim 14, wherein the liquid comprises water and the slurry contains at about 0.01 wt. % abrasive particles.

16. The process of claim 15, wherein the nucleic acid related compound is RNA or DNA, a nitrogen-containing precursor of RNA or DNA, a nitrogen-containing decomposition product of RNA or DNA, or mixture of any of these compounds.

17. The process of claim 16, wherein the nucleic acid related compound comprises RNA or DNA.

18. The process of claim 17, wherein the nucleic acid related compound comprises a nucleotide.

19. The process of claim 16, wherein the nucleic acid related compound comprises a nucleoside.

20. The process of claim 16, wherein the nucleic acid related compound comprises adenine, guanine, cytosine, uracil, thymine or mixtures thereof.

21. The process of claim 16, wherein the nucleic acid related compound is a mixture of uridine and cytidine.

22. The process of claim 18, wherein the nucleotide is adenosine 5′-phosphate, 2′-deoxyadenosine 5′-phosphate, guanosine 5′-phosphate, 2′-deoxyguanosine 5′-phosphate, cytidine 5′-phosphate, 2′-deoxycytidine 5′-phosphate, uridine 5′-phosphate, 2′-deoxythymidine 5′-phosphate, adenosine 5′-diphosphate, 2′-deoxyadenosine 5′-diphosphate, guanosine 5′-diphosphate, 2′-deoxyguanosine 5′-diphosphate, cytidine 5′-diphosphate, 2′-deoxycytidine 5′-diphosphate, uridine 5′-diphosphate, 2′-deoxythymidine 5′-diphosphate, adenosine 5′-triphosphate, 2′-deoxyadenosine 5′-triphosphate, guanosine 5′-triphosphate, 2′-deoxyguanosine 5′-triphosphate, cytidine 5′-triphosphate, 2′-deoxycytidine 5′-triphosphate, uridine 5′-triphosphate, 2′-deoxythymidine 5′-triphosphate, or mixtures thereof.

23. The process of claim 17, wherein the nucleoside is adenosine, 2′-deoxyadenosine, guanosine, 2′-deoxyguanosine, cytidine, 2′-deoxycytidine, uridine, 2′-deoxythymidine or mixtures thereof.

24. The process of claim 16, wherein the slurry contains a mixture of a cationic surfactant, an anionic surfactant and a nonionic surfactant.

25. The process of claim 24,
wherein the cationic surfactant is an alkyltrimethylammonium halide, an alkylbenzyldimethylammonium halide, a pyridiniumalkyl halide, an alkylammonium ester, or mixtures thereof,
wherein the anionic surfactant is a polymer containing carboxylic acid groups, an ammonium, sodium, potassium, cesium, monoethanolamine, diethanolamine, or triethanolamine salt of such a polymer, or mixtures thereof, and
wherein the nonionic surfactant is a water soluble polyvinyl alcohol, polyacrylamide, polyvinylpyrrolidone, or mixtures thereof.

26. The process of claim 25, wherein the cationic surfactant is hexadecyltrimethylammonium bromide, hexadecylbenzyldimethylammonium bromide, dodecylbenzyldimethylammonium bromide, cetylpyridinium chloride, dodecylammonium acetate, or mixtures thereof.

27. The process of claim 14, wherein the nucleic acid related compound is a uridine, cytidine or a mixture thereof.

28. The process of claim 14, wherein the nucleic acid related compound is RNA, DNA, a nucleoside, a nucleotide or a mixture of any of these compounds.

29. The process of claim 14, wherein the nucleic acid related compound is naturally-occurring.

30. The process of claim 14, wherein the nucleic acid related compound is synthetic.
